(19) United States
(12) Patent Application Publication
(10) Pub. No.: US 2007/0201207 A1
(43) Pub. Date: Aug. 30, 2007

(54) Chip Heat Dissipation System and Structure of Heat Exchange Device and Manufacturing Method Thereof

(76) Inventors: Ming-Hang Hwang, Taipei City (TW); Yu-Chiang Cheng, Taipei City (TW); Chao-Yi Chen, Taipei City (TW); Ping-Feng Lee, Taipei County (TW); Hsin-Lung Kuo, Taipei City (TW); Bin-Wei Lee, Taipei City (TW); Wei-Chung Hsiao, Taipei City (TW)

Correspondence Address: LAW OFFICES OF LAI AND ASSOCIATES, P.C., 5800 RANCHESTER STE 200, HOUSTON, TX, 77036, US

(21) Appl. No.: 11/307,853

(22) Filed: Feb. 24, 2006

(51) Int. Cl. H05K 7/20

(52) U.S. Cl. 361/701

(57) ABSTRACT

This invention discloses a chip heat dissipation system for a chip in heat dissipating and a manufacturing method and a structure of heat dissipation device. The chip heat dissipation system includes a heat dissipation device, a heat exchange device, a pump assembly device and at least two pipes. This heat dissipation device is used for receiving waste heat generate from the chip, then heat exchange device is used for discharging waste heat. Moreover, the heat exchange device is composed of a thermal conduction material, including a metal material and a bracket structure of carbon element. Also, the pipes are used for connecting at least two connection ends of the heat dissipation device and the heat exchange device and then the pump assembly device is used for circulating a fluid between the heat dissipation device and the heat exchange device by the pipes. The bracket structure of carbon element has high thermal conductivity, so as to improve the heat conduction efficiency. The manufacturing method for thermal conduction material can be made with chemical vapor deposition, physical vapor deposition, melting or the other material preparations. The bracket structure of carbon element can be coated on the metal material surface and can also be mixed into the metal material.

### FIELD OF THE INVENTION

The present invention relates to a chip heat dissipation system and a structure of a heat exchange device of the chip heat dissipation system and a manufacturing method and, more particularly, to the heat exchange device is composed of a heat conduction material which includes a metal and a bracket structure of carbon element.

### BACKGROUND OF THE INVENTION

In recent years, the pace of high technology industry development is extremely fast. The development of electronic components is toward smaller volumes and high densities. The performance requirements for the aforesaid components also increase. Much waste heat is then generated. The efficiency of the electronic components will be decreased if the waste heat is unable to eliminate appropriately. Therefore, various heat conduction materials are provided to improve the efficiency of heat dissipation.

Referring to FIG. 1, a schematic diagram illustrates a conventional air blown chip heat dissipation system. The air blown chip heat dissipation system includes a chip 11, a substrate 12 and a heat dissipation device 13. The chip 11 has a plurality of pins 111 for connecting to the substrate 12. The substrate 12 is a motherboard and a display card. The heat dissipation device 13 includes a fan 131 and is stuck by thermal grease 132 on the chip 11. The waste heat generated from the chip 11 is conducted by the thermal grease 132 to the heat dissipation device 13. The waste heat within the heat dissipation device 13 is then discharged by an air stream produced by the fan 131 to an outside.

However, the efficiency of heat dissipation is restricted by the size of the fan 131 and the rotation speed. The waste heat within the heat dissipation device 13 may not be discharged to the outside appropriately. In another word, the waste heat generated by the chip 11 may not be conducted to the heat dissipation device 13 instantly. The performance of the chip 11 is then getting worse due to the accumulation of waste heat.

Referring to FIG. 2, a schematic diagram illustrates conventional water cooling chip heat dissipation system. The water cooling chip heat dissipation system includes a chip 21, a substrate 22, a heat dissipation device 23, a heat exchange device 24 and a pump assembly device 25. The chip 21 further has a plurality of pins 211 for connecting to the substrate 22. The substrate 22 is a motherboard and a display card. The heat dissipation device 23 is stuck by thermal grease 231 on the chip 21. The pump assembly device 25, the heat dissipation device 23 and the heat exchange device 24 are connected each other through heat pipes 251. The pump assembly device 25 could lead water to circulate between the heat dissipation device 23 and the heat exchange device 24 via the heat pipes 251.

The waste heat generated from the chip 21 is conducted by the thermal grease 231 to the heat dissipation device 23. The waste heat within the heat dissipation device 23 is then taken to the heat exchange device 24 through water circulation. The heat exchange device 24 further includes a fan 241. The waste heat is then discharged by an air stream produced from the fan 241 to the outside.

Water has high specific heat coefficient and is used to be the heat dissipation manner of the mentioned above for conducting the waste heat to the heat exchange device 24. The efficiency of heat dissipation can be improved when the pump assembly device 25 accelerates the circulation speed of water. There is no restriction in volume because the heat exchange device 24 is not set on the substrate 22. In other words, the efficiency of heat dissipation can be improved by increasing the size of the fan 241 and the rotation speed. The efficiency of heat dissipation for the chip 21 can also be improved through the system.

However, if heat conduction of the material of the heat exchange device is bad, the heat exchange device may not receive the waste heat taken by water, and the efficiency of heat dissipation may not be satisfied either. The heat conduction material used in the heat exchange device includes aluminum, copper, silver or alloys. These materials may not satisfy the requirement of high heat dissipation when the performance of the chip and the generation rate of the waste heat increase substantially. Therefore, an alternative heat conduction material is an important issue.

In addition, diamonds are well known and have characteristics with the highest hardness, the fastest heat conduction, and the widest refraction range in current materials. Diamonds are always one of more important materials in engineering due to its excellent characteristics. The thermal conductivity of diamonds at the normal atmospheric temperature is five times more than copper. Moreover, the thermal expansion factor of diamonds at high temperature is very small that shows the excellent efficiency for heat dissipating. The feature may help people to differentiate the adulteration of diamonds. In the prior art, many technologies and manufacture procedures have been developed to make diamonds. The direct decomposition for hydrocarbons is the most familiar method like Microwave Plasma Enhance Chemical Vapor Deposition (MPCVD) and Hot Filament CVD (HFCVD). By the aforesaid methods, polycrystalline diamond films can be deposited. The characteristic of the polycrystalline diamond films is the same as the single crystal diamonds.

Accordingly, the heat conduction material includes a metal and a bracket structure of carbon element (e.g. diamond material) so as to improve thermal conductivity.

### SUMMARY OF THE INVENTION

Briefly, the object of the present invention is to provide a chip heat dissipation system, a structure of a heat exchange device of the chip heat dissipation system and a manufacturing method. The chip heat dissipation system comprises a chip, a heat dissipation device, a heat exchange device, a pump assembly device and a plurality of heat pipes. The heat exchange device includes a plurality of heat dissipation slips with fin shape. The heat dissipation slips with fin shape are made by metal injection molding, cutting molding, punch or powder injection molding. The heat dissipation slips with fin shape are further formed to be the heat exchange device through welding and folding. A plurality of holes can be formed on the heat dissipation slip with fin shape of the heat exchange device by using a drilling machine. The heat exchange device is composed of a heat conduction material. The heat conduction material includes a metal and a bracket structure of carbon element. The metal can be copper, aluminum, silver or an alloy or other metal material with high thermal conductivity. The bracket structure of carbon element is diamonds. The bracket structure of carbon element can be coated on a surface of the metal or can be mixed into the metal. The heat conduction material for use in the heat exchange device can be made by chemical vapor deposition (CVD), physical vapor deposition (PVD), melting, metal injection molding or other material preparations. The bracket structure of carbon element can be coated on or mixed into a surface of the heat exchange device. The efficiency of heat dissipation for the heat exchange device can be improved substantially.

The chip heat dissipation system and the structure of the heat exchange device and the method could satisfy the efficiency of heat dissipation for current chips. The operation quality of the chips can also be improved.

Other features and advantages of the present invention and variations thereof will become apparent from the following description, drawings, and claims.

### BRIEF DESCRIPTION OF THE DRAWINGS

FIG. 1 is a schematic diagram illustrating a conventional air blown chip heat dissipation system;

FIG. 2 is a schematic diagram illustrating a conventional water cooling chip heat dissipation system;

FIG. 3 is a schematic diagram illustrating a water cooling chip heat dissipation system according to an embodiment of the present invention;

FIG. 4 is a schematic diagram illustrating a heat dissipation slip with fin shape of a heat exchange device according to an embodiment of the present invention;

FIG. 5 is a schematic diagram illustrating heat dissipation slips set with fin shape of a heat exchange device made by welding according to an embodiment of the present invention;

FIG. 6 is a schematic diagram illustrating a metal injection molding for making a heat exchange device of a chip heat dissipation system according to an embodiment of the present invention;

FIG. 7 is a schematic diagram illustrating microwave plasma enhanced chemical vapor deposition for making a heat exchange device of a chip heat dissipation system according to an embodiment of the present invention; and

FIG. 8 is a schematic diagram illustrating ion beam sputtering for making a heat exchange device of a chip heat dissipation system according to an embodiment of the present invention.

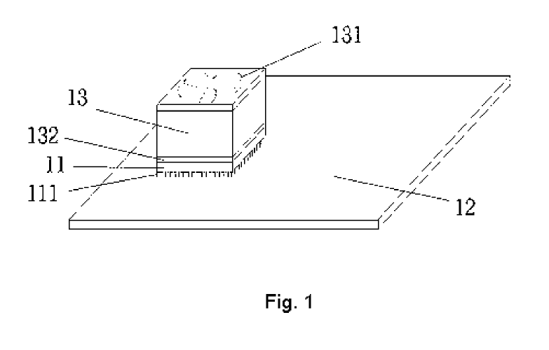

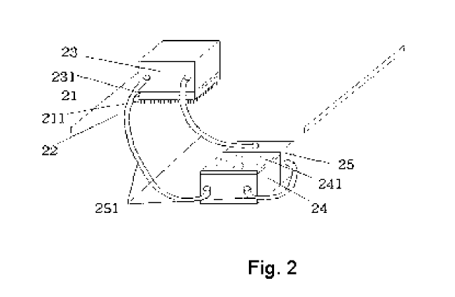

### DETAILED DESCRIPTION OF THE PREFERRED EMBODIMENTS

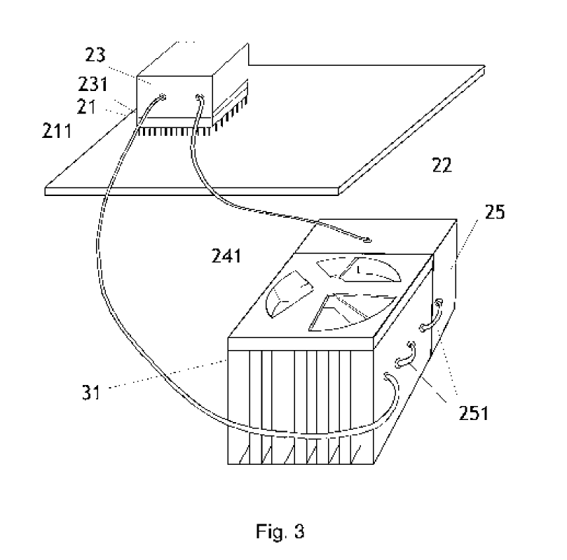

Referring to FIG. 3, a schematic diagram illustrates a chip heat dissipation system according to an embodiment of the present invention. The chip heat dissipation system comprises a chip 21, a substrate 22, a heat dissipation device 23, a heat exchange device 31 and a pump assembly device 25. The chip 21 is a central processing chip and has a plurality of pins 211 for connecting to the substrate 22. The substrate 22 is a motherboard and a display card. The heat dissipation device 23 is stuck by thermal grease on the chip 21. The pump assembly device 25, the heat dissipation device 23 and the heat exchange device 31 are connected each other through the heat pipes 251. The pump assembly device 25 could circulate a fluid with high specific heat coefficient between the heat dissipation device 23 and the heat exchange device 31. The heat exchange device 31 is composed of a heat conduction material. The heat conduction material includes a metal and a bracket structure of carbon element. The metal can be copper, aluminum, silver, other alloys or other metals with high thermal conductivity. The bracket structure of carbon element is diamonds. In addition, the bracket structure of carbon element can be coated on a surface of the metal or can be mixed into the metal.

Waste heat generate by the operation of the chip 21 is conducted by the thermal grease 231 to the heat dissipation device 23. The waste heat is then conducted to the heat exchange device 31 through the circulation of the fluid. Water is provided to be the fluid. The heat exchange device 31 further has an air stream produce device 241. The waste heat within the heat exchange device 31 is then discharged by an air stream produced by the air stream produce device 241 to an outside.

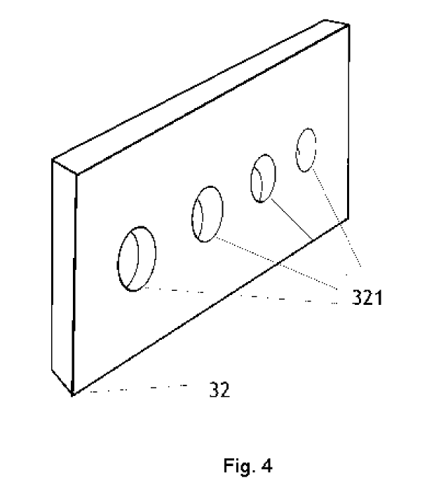

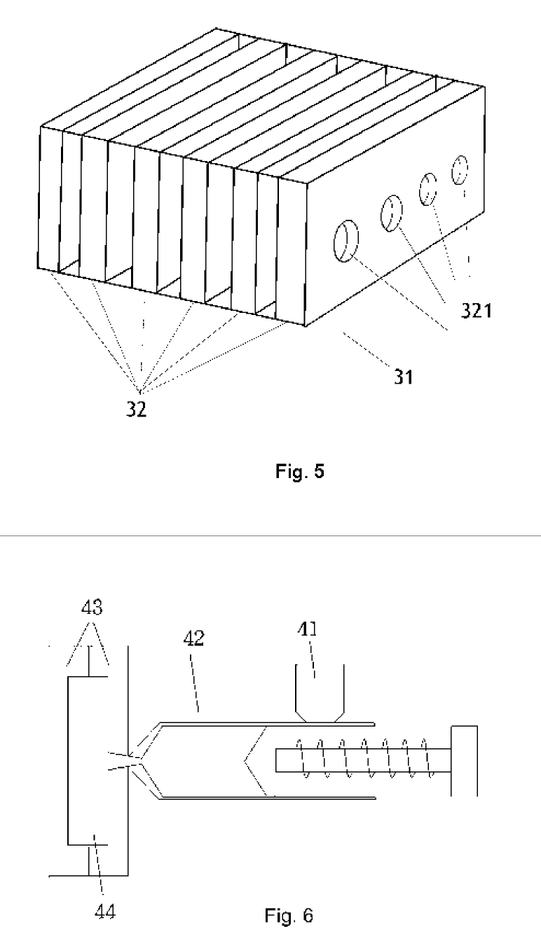

Referring to FIG. 4, a schematic diagram illustrates a heat dissipation slip 32 with fin shape of the heat exchange device 31 according to FIG. 3. At least a hole 321 is formed by a drilling machine. The heat pipes 251 can be placed into the hole 321. The heat exchange device 31 is composed of welding. The heat dissipation device includes a metal and a bracket structure of carbon element. The metal can be copper, aluminum, silver or alloys or other metals with high thermal conductivity. The bracket structure of carbon element is diamonds. Referring to FIG. 5, the heat exchange device 31 formed by welding is for providing the heat pipe 251 as shown in FIG. to penetrate the holes 321 formed on the heat dissipation slips. The heat dissipation slips includes a metal and a bracket structure of carbon element. The metal can be copper, aluminum, silver or alloys or other metals with high thermal conductivity. The bracket structure of carbon element is diamonds. The holes 321 formed on the heat dissipation slips could provide an opening for the fluid. The waste heat is conducted by the fluid to the heat exchange device 31. The waste heat is then discharged by the air stream produced by the air stream produce device 241 to the outside.

The heat exchange device 31 is composed of a heat conduction material with high thermal conductivity. The heat exchange device 31 could receive the waste heat taken by water. The fluid pressurized by the pump assembly device 25 could circulate between the heat dissipation device 23 and the heat exchange device 31. The waste heat within the heat dissipation device 23 is then conducted to the heat exchange device 31. The waste heat within the heat exchange device 31 is then discharged by the air stream produced by the air stream produce device 31 to the outside so as to improve the efficiency of heat dissipation for entire system.

Referring to FIG. 6, a schematic diagram illustrates a metal injection molding for making the heat exchange device of the chip heat dissipation system according to an embodiment of the present invention. The injection molding comprises a mold material supplier 41, a mold material injector 42 and a mold 43. A mold material is injected by the mold material injector 42 to a mold cavity 44 of the mold 43 for molding. The mold material is a metal or a melting material which has a metal and a bracket structure of carbon element. The metal is copper or aluminum or silver or other metals with high thermal conductivity or other material combinations. The melting point of the bracket structure of carbon element is higher than any metal of the mentioned above. Therefore, the bracket structure of carbon element can be mixed into those metals so as to form the mold material. A structure of metal injection molding is a shape of the mold cavity 44. In the embodiment, the shape of the mold cavity 44 is the structure of the heat dissipation slips 32 with fin shape as shown in FIG. 4. At least a hole 321 is formed by the drilling machine. The heat dissipation slip set is then formed by welding as shown in FIG. 5. Lastly, the heat exchange device 31 as shown in FIG. 3 is formed.

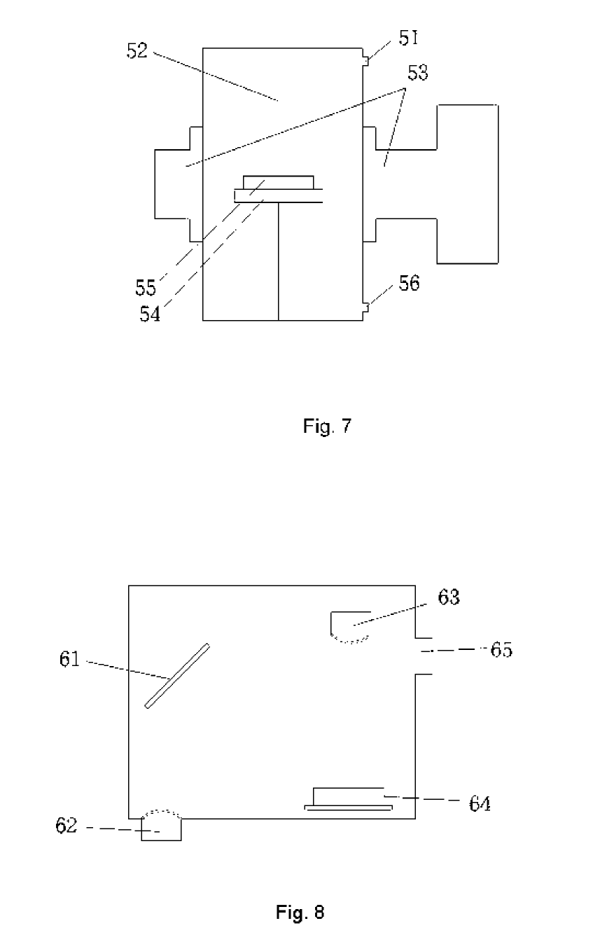

Referring to FIG. 7, a schematic diagram illustrates microwave plasma enhanced chemical vapor deposition for making the heat exchange device of the chip heat dissipation system according to an embodiment of the present invention. The bracket structure of carbon element is coated on a surface of the metal, especially for the surface of the heat exchange device 31 as shown in FIG. 3. The reaction procedure is that a mixed gas for desired reaction is delivered to a gas reaction room 52 from a gas inlet 51. At the same time, a microwave is generated by a microwave generation system 53 to activate the mixed gas in order to provide reactive ions for reacting. The reactive ions are absorbed to coat on a surface of a metal material 55 held by a carrier 54 so as to form diamond films. The metal material 55 is the heat exchange device which is formed by the way described in FIG. 6. The heat exchange device can be copper or aluminum or silver or other metals with high thermal conductivity or other material combinations. Remaining gas is discharged via a waste gas outlet 56. By the way mentioned above, a heat conduction material coating with diamond particles can be acquired. In the embodiment, the metal material 55 combines with the diamond films so as to form the heat exchange device 31 as shown in FIG. 3.

Referring to FIG. 8, a schematic diagram illustrates ion beam sputtering for making the heat exchange device of the chip heat dissipation system according to another embodiment of the present invention. Ion beam sputtering is a physical vapor deposition (PVD) and is for coating the bracket structure of carbon element on a surface of the metal, especially for the surface of the heat exchange device 31 as shown in FIG. 3. In the embodiment, the manufacturing procedure is that a target 61 is molded by diamond materials first of all. The placement angle of the target 61 and the shooting direction of ion beam of a first ion gun 62 are approximately forty five degrees. The diamond particles shot by the first ion gun 62 fly to the front of a second ion gun 63. The diamond particles is then sputtered on the surface of a metal material 64 to form uniform diamond films by providing enough kinetic energy from the second ion gun 63. The metal material 64 is a heat dissipation device which is formed by the way described in FIG. 6. The heat dissipation device can be copper or aluminum or silver or other metals with high thermal conductivity or material combinations. The remaining diamond particles are discharged by a waste gas outlet 65. In the embodiment, the metal material 64 combines with the diamond films so as to form the heat exchange device 31 as shown in FIG. 3.

Although the features and advantages of the embodiments according to the preferred invention are disclosed, it is not limited to the embodiments described above, but encompasses any and all modifications and changes within the spirit and scope of the following claims.

What is claimed is:

1. A chip heat dissipation system for use in a chip for heat dissipation, comprising:
a heat dissipation device received a waste heat generated by the chip;
a heat exchange device discharged the waste heat, the heat exchange apparatus composed of a heat conduction material, the heat conduction material combined a metal with a bracket structure of carbon element;
at least two heat pipes connected to at least two connection ends of the heat dissipation apparatus and the heat exchange apparatus respectively; and
a pump assembly device circulated a fluid between the heat dissipation device and the heat exchange device through the heat pipes.

2. The chip heat dissipation system of claim 1, wherein the chip is a central processing chip.

3. The chip heat dissipation system of claim 1, wherein the bracket structure of carbon element is diamonds.

4. The chip heat dissipation system of claim 1, wherein the metal is copper.

5. The chip heat dissipation system of claim 1, wherein the metal is silver.

6. The chip heat dissipation system of claim 1, wherein the metal is aluminum.

7. The chip heat dissipation system of claim 1, wherein the metal is a metal alloy with high thermal conductivity.

8. The chip heat dissipation system of claim 1, wherein the heat conduction material is made be chemical vapor deposition (CVD).

9. The chip heat dissipation system of claim 1, wherein the heat conduction material is made by physical vapor deposition (PVD).

10. The chip heat dissipation system of claim 1, wherein the heat conduction material is made by melting.

11. The chip heat dissipation system of claim 1, wherein the heat exchange device has a plurality of heat dissipation slips with fin shape.

12. The chip heat dissipation system of claim 11, wherein the heat dissipation slips with fin shape are formed by injection molding.

13. The chip heat dissipation system of claim 11, wherein the heat dissipation slips with fin shape are formed by cutting molding.

14. The chip heat dissipation system of claim 11, wherein the heat dissipation slips with fin shape are formed by punch.

15. The chip heat dissipation system of claim 11, wherein the heat dissipation slips with fin shape are formed by powder injection molding.

16. The chip heat dissipation system of claim 11, wherein the heat dissipation slips with fin shape are formed by folding, so as to form the heat exchange device.

17. The chip heat dissipation system of claim 11, wherein the heat dissipation slips with fin shape are formed by welding, so as to form the heat exchange device.

18. The chip heat dissipation system of claim 11, wherein the heat dissipation slips with fin shape are formed by drilling, so as to form a plurality of holes.

19. The chip heat dissipation system of claim 11, wherein the heat dissipation slips with fin shape are composed of the heat conduction material.

20. The chip heat dissipation system of claim 1, wherein the heat exchange device further includes an air stream produce device.

21. The chip heat dissipation system of claim 20, wherein the air stream produce device is a fan.

22. The chip heat dissipation system of claim 1, wherein the fluid is water.

23. A manufacture method for making a heat exchange device, comprising:
employing a manufacture to produce a heat conduction material having a metal and a bracket structure of carbon element;
employing a forming to shape the heat conduction material into heat dissipation slips with fin shape;
employing a drilling to shape a plurality of holes on the heat dissipation slips with fin shape; and
employing a assembly to assemble the heat dissipation slips with fin shape into the heat exchange device.

24. The manufacture method of claim 23, wherein further comprises providing a cutting molding to form the heat dissipation slips with fin shape.

25. The manufacture method of claim 23, wherein further comprises providing a powder injection molding to form the heat dissipation slips with fin shape.

26. The manufacture method of claim 23, wherein further comprises providing a drilling machine to drill the plurality of holes.
